(19) United States
(12) Patent Application Publication
(10) Pub. No.: US 2026/0293741 A1
(43) Pub. Date: Sep. 24, 2026

(54) ADHESIVE AGENT COMPOSITION, ADHESIVE AGENT FILM FOR CIRCUIT CONNECTION, CIRCUIT CONNECTION STRUCTURE, AND METHOD FOR MANUFACTURING SAME

(71) Applicant: Resonac Corporation, Tokyo (JP)

(72) Inventors: Shinnosuke IWAMOTO, Tokyo (JP); Sunao KUDO, Tokyo (JP)

(21) Appl. No.: 19/480,080

(22) PCT Filed: Jul. 4, 2024
(86) PCT No.: PCT/JP2024/024287

§ 371 Date: Oct. 30, 2025

(30) Foreign Application Priority Data
Jul. 7, 2023 (JP) 2023-112356

(51) Int. Cl. H10W 72/49; C09J 7/35; H05K 1/11; H05K 1/181; H05K 3/321; H05K 3/36; H10W 72/00; H10W 90/00

(52) U.S. Cl. CPC H10W 72/49; C09J 7/35; H05K 1/111; H05K 1/181; H05K 3/323; H05K 3/361; H10W 72/074; H10W 90/701; C09J 2203/326; C09J 2301/304; C09J 2301/314; C09J 2301/408; H05K 2201/0129; H05K 2201/042; H05K 2201/068; H05K 2201/10015; H05K 2201/10022; H05K 2201/10984; H05K 2203/1194

(57) ABSTRACT

An adhesive agent film for circuit connection contains a thermoplastic resin, a thermosetting component, conductive particles, and a non-conductive filler, in which the non-conductive filler includes a non-conductive filler MF having an average linear thermal expansion coefficient of 0 ppb/° C. or less from 30° C. to 150° C.

### TECHNICAL FIELD

The present invention relates to an adhesive agent composition, an adhesive agent film for circuit connection, a circuit connection structure, and a method for manufacturing the same.

### BACKGROUND ART

As a circuit connecting material for a semiconductor element or a liquid crystal display element, a thermosetting resin using an epoxy resin exhibiting high adhesion and high reliability is known (see, for example, Patent Literature 1). As a constituent component of the resin, a curing agent such as an epoxy resin or a phenol resin having reactivity with the epoxy resin, and a latent curing agent accelerating the reaction between the epoxy resin and the curing agent are generally used. The latent curing agent is an important factor for determining a curing temperature and a curing rate, and various compounds are used from the viewpoint of storage stability at room temperature and a curing rate during heating.

Furthermore, recently, a radically curable adhesive agent using an acrylate derivative and/or a methacrylate derivative (hereinafter, collectively referred to as “(meth)acrylate derivatives”) in combination with a peroxide as a radical polymerization initiator has attracted attention. In radical curing, radicals which are reactive active species are highly reactive, and thus short-time curing is possible (see, for example, Patent Literatures 2 and 3).

### CITATION LIST

### Patent Literature

Patent Literature 1: Japanese Unexamined Patent Publication No. H1-113480
Patent Literature 2: Japanese Unexamined Patent Publication No. 2002-203427
Patent Literature 3: International Publication WO 98/044067

### SUMMARY OF INVENTION

### Technical Problem

Incidentally, an adhesive agent film having anisotropic conductivity in which conductive particles are dispersed in an adhesive agent is used for connecting circuit members. In a circuit connection structure manufactured using such an adhesive agent film, a connection portion in which opposing electrodes are electrically connected via conductive particles is formed. The connection portion contains a cured product of an adhesive agent containing a thermosetting component as described above, thereby fixing the conductive particles and the electrode.

Conductivity between electrodes in the circuit connection structure can be improved by the conductive particles, but the circuit connection structure is also required to have characteristics in which connection resistance between opposing electrodes is less likely to increase even under high-temperature and high-humidity conditions (hereinafter, also referred to as “high-temperature and high-humidity connection reliability”). Furthermore, in the field of circuits for liquid crystal display elements and the like, a circuit is being narrowed, and mounting at a lower temperature in a shorter time is required in order to reduce thermal damage to the circuit. Under such mounting conditions, the reactivity of the adhesive agent film decreases, so that it is difficult to obtain high-temperature and high-humidity connection reliability.

Therefore, an object of the present invention is to provide an adhesive agent composition and an adhesive agent film for circuit connection capable of obtaining a circuit connection structure excellent in high-temperature and high-humidity connection reliability, and a circuit connection structure excellent in high-temperature and high-humidity connection reliability and a method for manufacturing the same.

### Solution to Problem

The present inventors have conventionally obtained a finding that peeling may occur at an interface between a circuit member and a resin cured product by observing a connection portion of a circuit connection structure after a high-temperature and high-humidity test. When interface peeling occurs around the contact portion between the conductive particles and the electrode, the contact area decreases, and the connection resistance may increase. Furthermore, according to the study of the present inventors, it has become clear that such interface peeling is likely to occur in a case where a non-conductive filler is highly blended for the purpose of improving the high-temperature and high-humidity connection reliability. Therefore, as a result of further intensive studies, the present inventors have found that the area of the interface peeling can be reduced even after a more severe high-temperature and high-humidity test by blending a specific non-conductive filler, and have completed the present invention.

The gist of the present invention is the following [1] to [9].
[1] An adhesive agent composition containing: a thermosetting component; conductive particles; and a non-conductive filler, in which the non-conductive filler includes a non-conductive filler MF having an average linear thermal expansion coefficient of 0 ppb/° C. or less from 30° C. to 150° C.
[2] The adhesive agent composition described in [1], in which a content of the non-conductive filler MF is 0.1 to 50 mass % based on a total mass of the adhesive agent composition excluding the conductive particles and the non-conductive filler.
[3] The adhesive agent composition described in [1] or [2], containing a radical polymerizable compound and a radical polymerization initiator as the thermosetting component.
[4] The adhesive agent composition described in any one of [1] to [3], further containing a thermoplastic resin.
[5] The adhesive agent composition described in any one of [1] to [4], in which a reaction rate when the adhesive agent composition is heated at 180° C. for 1 minute is 90% or more.
[6] An adhesive agent film for circuit connection, containing: a thermoplastic resin; a thermosetting component; conductive particles; and a non-conductive filler, in which the non-conductive filler includes a non-conductive filler MF having an average linear thermal expansion coefficient of 0 ppb/° C. or less from 30° C. to 150° C.
[7] The adhesive agent film for circuit connection described in [6], in which a content of the non-conductive filler MF is 0.1 to 50 mass % based on a total mass of the adhesive agent film excluding the conductive particles and the non-conductive filler.
[8] The adhesive agent film for circuit connection described in [6] or [7], containing a radical polymerizable compound and a radical polymerization initiator as the thermosetting component.
[9] The adhesive agent film for circuit connection described in any one of [6] to [8], in which a reaction rate when the adhesive agent film for circuit connection is heated at 180° C. for 1 minute is 90% or more.
[10] A circuit connection structure including: a first circuit member having a first electrode; a second circuit member having a second electrode; and a connection portion disposed between the first circuit member and the second circuit member and electrically connecting the first electrode and the second electrode to each other, in which the connection portion contains conductive particles and a non-conductive filler MF having an average linear thermal expansion coefficient of 0 ppb/° C. or less from 30° C. to 150° C.
[11] The circuit connection structure described in [10], in which the connection portion contains a cured product of the adhesive agent composition described in any one of [1] to [5].
[12] A method for manufacturing a circuit connection structure, the method including a step of heating and pressurizing a first circuit member having a first electrode, a second circuit member having a second electrode, and the adhesive agent film for circuit connection described in any one of [6] to [8] in a state where the first electrode and the second electrode are disposed to face each other with the adhesive agent film for circuit connection interposed therebetween so as to electrically connect the first electrode and the second electrode.

### Advantageous Effects of Invention

According to the present invention, it is possible to provide an adhesive agent composition and an adhesive agent film for circuit connection capable of obtaining a circuit connection structure excellent in high-temperature and high-humidity connection reliability, and a circuit connection structure excellent in high-temperature and high-humidity connection reliability and a method for manufacturing the same.

### BRIEF DESCRIPTION OF DRAWINGS

FIG. 1 is a schematic cross-sectional view illustrating one embodiment of a connection structure.

### DESCRIPTION OF EMBODIMENTS

In the present specification, a numerical range indicated using “to” indicates a range including numerical values described before and after “to” as a minimum value and a maximum value, respectively. In the numerical range described in stages in the present specification, the upper limit value or the lower limit value of the numerical range of a certain stage may be replaced with the upper limit value or the lower limit value of the numerical range of another stage. Furthermore, in the numerical range described in the present specification, the upper limit value or the lower limit value of the numerical range may be replaced with a value shown in Examples. Furthermore, the upper limit value and the lower limit value described individually can be arbitrarily combined. Furthermore, in the present specification, “(meth)acrylate” means at least one of an acrylate and a methacrylate corresponding thereto. The same applies to other similar expressions such as “(meth)acryloyl”. Furthermore, “(poly)” means both cases where there is a prefix of“poly” and where there is no prefix of “poly”. Furthermore, “A or B” only needs to include either A or B, and may include both A and B. Furthermore, as for the materials exemplified below, one type may be used singly or two or more types may be used in combination unless otherwise specified. In a case where a plurality of substances corresponding to each component are present in a composition, the content of each component in the composition means a total amount of the plurality of substances present in the composition, unless otherwise specified.

Hereinafter, embodiments of the present invention will be described in detail with reference to the drawings as the case may be. However, the present invention is not limited to the following embodiments.

### <Adhesive Agent Composition>

An adhesive agent composition of the present embodiment contains a thermosetting component, conductive particles, and a non-conductive filler.

As the thermosetting component, a radical polymerizable compound and a radical polymerization initiator, or a combination of an epoxy resin and a curing agent can be used.

In the present embodiment, from the viewpoint of shortening the production time and handleability, (A) a thermoplastic resin (hereinafter, also referred to as “component (A)”), (B) a radical polymerizable compound (hereinafter, also referred to as “component (B)”), and (C) a radical polymerization initiator (hereinafter, also referred to as “component (C)”) can be contained.

### [Component (A): Thermoplastic Resin]

As the component (A), a polyvinyl butyral resin, a polyvinyl formal resin, a polyamide resin, a polyester resin, a phenol resin, an epoxy resin, a phenoxy resin, a polystyrene resin, a xylene resin, a polyurethane resin, a polyester urethane resin, or the like can be used. These can be used singly or in combination of two or more kinds thereof.

The weight average molecular weight of the thermoplastic resin may be 1.0×10⁴ or more from the viewpoint of film formability and the like, and may be 1.0×10⁴ or more and less than 1.0×10⁶ from the viewpoint of mixing properties.

The weight average molecular weight of the thermoplastic resin refers to a value measured by gel permeation chromatography (GPC) under the following conditions using a calibration curve by a standard polystyrene.

### [GPC Conditions]

Equipment used: Hitachi L-6000 type [Hitachi, Ltd.], Column: gel pack GL-R420+gel pack GL-R430+gel pack GL-R440 (3 in total) [manufactured by Resonac Corporation], Eluent: tetrahydrofuran, Measurement temperature: 40° C., Flow rate: 1.75 mil/min, Detector: L-3300RI [Hitachi, Ltd.]

Furthermore, as the component (A), a hydroxyl group-containing resin (for example, a phenoxy resin) having a Tg (glass transition temperature) of 40° C. or higher and a weight average molecular weight of 1.0×10⁴ or more can be used. The hydroxyl group-containing resin may be modified with an epoxy group-containing elastomer.

Note that, in the present specification, a thermoplastic resin having a radically polymerizable functional group is blended as the radical polymerizable compound (B).

The phenoxy resin can be obtained by reacting a bifunctional phenol with epihalohydrin to a high molecular weight or by polyaddition reacting a bifunctional epoxy resin with a bifunctional phenol.

Furthermore, as the component (A), a polyester urethane resin may be used.

From the viewpoint of further improving the effect of suppressing peeling, the content of the component (A) in the adhesive agent composition may be 5 mass % or more or 30 mass % or more, may be 80 mass % or less or 60 mass % or less, and may be 5 to 80 mass % or 30 to 60 mass %, based on the resin components (for example, components other than the conductive particles and the non-conductive filler) of the adhesive agent composition.

### [Component (B): Radical Polymerizable Compound]

As the component (B), a compound having a radically polymerizable functional group can be used. Examples of the radically polymerizable functional group include a vinyl group, an acryloyl group, and a methacryloyl group. Among them, a compound having an acryloyl group and/or a methacryloyl group is more preferable. The component (B) can be used singly or in combination of two or more kinds thereof.

In the adhesive agent composition of the present embodiment, as the component (B), a polymer such as polyurethane, polystyrene, polyethylene, polyvinyl butyral, polyvinyl formal, polyimide, polyamide, polyester, polyvinyl chloride, polyphenylene oxide, a urea resin, a melamine resin, a phenol resin, a xylene resin, an epoxy resin, a polyisocyanate resin, or a phenoxy resin can also be used. Note that the polymer used as the component (B) has at least one radically polymerizable functional group in the molecule.

It is preferable that the polymer is contained as the component (B) because the polymer has favorable handleability and excellent stress relaxation during curing, and it is more preferable that the polymer has a functional group such as a hydroxyl group because adhesion is improved.

The weight average molecular weight of the polymer may be 1.0×10⁴ or more, and may be 1.0×10⁴ or more and 1.0×10⁶ or less from the viewpoint of mixing properties. The weight average molecular weight here is measured by gel permeation chromatography (GPC) under the conditions described in Examples using a calibration curve by a standard polystyrene.

From the viewpoint of improving the high-temperature and high-humidity connection reliability, as the component (B), a (poly)urethane (meth)acrylate compound can be used.

The content of the (poly)urethane (meth)acrylate compound may be 40 to 95 mass %, 50 to 90 mass %, or 55 to 85 mass % based on the total mass of the component (B) from the viewpoint of a balance between the crosslinking density and the curing shrinkage.

As the component (B), ethylene glycol di(meth)acrylate, diethylene glycol di(meth)acrylate, trimethylolpropane tri(meth)acrylate, tetramethylolmethane tetra(meth)acrylate, 2-hydroxy-1,3-di(meth)acryloxypropane, 2,2-bis[4-((meth)acryloxymethoxy)phenyl]propane, 2,2-bis[4-((meth)acryloxypolyethoxy)phenyl]propane, dicyclopentenyl(meth)acrylate, tricyclodecanyl(meth)acrylate, tris((meth)acryloyloxyethyl)isocyanurate, urethane (meth)acrylate, dimethyloltricyclodecane di(meth)acrylate, isocyanuric acid EO (ethylene oxide)-modified diacrylate, 2-methacryloyloxyethyl acid phosphate, and the like can be used.

Furthermore, as the component (B), a component having at least one partial structure selected from the group consisting of a dicyclopentane skeleton, a tricyclodecane skeleton, and a triazine ring can be used.

The component (B) may contain a (meth)acrylate compound having a tricyclodecane skeleton from the viewpoint of balancing the crosslinking density and the curing shrinkage and further reducing the connection resistance. The content of the (meth)acrylate compound having a tricyclodecane skeleton may be 0 to 90 mass %, 5 to 60 mass %, or 10 to 30 mass %, for example, based on the total mass of the component (B), from the viewpoint of a balance between the crosslinking density and the curing shrinkage.

The component (B) may contain a (meth)acrylate compound represented by the following Formula (1) (a (meth)acrylate compound having a phosphoric ester structure). In this case, since the adhesion strength to the surface of an inorganic substance (such as a metal) is improved, it is suitable for adhesion between electrodes (for example, between circuit electrodes).

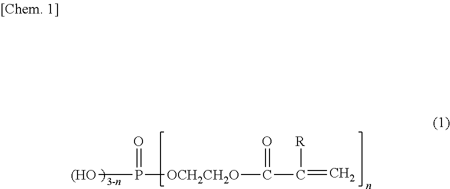

In Formula (1), n represents an integer of 1 to 3, and R represents a hydrogen atom or a methyl group.

The (meth)acrylate compound represented by Formula (1) is obtained, for example, by reacting phosphoric anhydride with 2-hydroxyethyl (meth)acrylate. Specific examples of the (meth)acrylate compound represented by Formula (1) include mono(2-(meth)acryloyloxyethyl) acid phosphate and di(2-(meth)acryloyloxyethyl) acid phosphate.

The content of the (meth)acrylate compound represented by Formula (1) may be 1 to 10 mass %, 2 to 5 mass %, or 2.5 to 4 mass %, for example, based on the total mass of the component (B), from the viewpoint of reducing the connection resistance and easily obtaining a crosslinking density necessary for improving the connection reliability.

From the viewpoint of reducing the connection resistance and easily obtaining a crosslinking density necessary for improving the high-temperature and high-humidity connection resistance reliability, the content of the component (B) in the adhesive agent film for circuit connection may be 5 mass % or more, 20 mass % or more, or 40 mass % or more, may be 90 mass % or less, 75 mass % or less, or 60 mass % or less, and may be 5 to 90 mass %, 20 to 75 mass %, or 40 to 60 mass %, based on the total mass of the resin components (for example, components other than the conductive particles and the non-conductive filler) of the adhesive agent composition.

### [Component (C): Radical Polymerization Initiator]

As the component (C), a compound that generates free radicals can be used, and examples thereof include compounds that are decomposed by heating to generate free radicals, such as a peroxide compound and an azo compound. The radical polymerization initiator is appropriately selected depending on the intended connection temperature, connection time, and the like. The component (C) can be used singly or in combination of two or more kinds thereof.

Examples of the radical polymerization initiator include diacyl peroxides, peroxy dicarbonates, peroxy esters, peroxy ketals, dialkyl peroxides, and hydroperoxides.

Examples of the diacyl peroxides include 2,4-dichlorobenzoyl peroxide, 3,5,5-trimethylhexanoyl peroxide, octanoyl peroxide, lauroyl peroxide, stearoyl peroxide, succinic peroxide, benzoylperoxytoluene, and benzoyl peroxide.

Examples of the peroxy dicarbonates include di-n-propyl peroxy dicarbonate, diisopropyl peroxy dicarbonate, bis(4-t-butylcyclohexyl)peroxy dicarbonate, di-2-ethoxymethoxyperoxy dicarbonate, di(2-ethylhexylperoxy)dicarbonate, dimethoxybutyl peroxy dicarbonate, and di(3-methyl-3-methoxybutylperoxy)dicarbonate.

Examples of the peroxy esters include 1,1,3,3-tetramethylbutyl peroxyneodecanoate, 1-cyclohexyl-1-methylethyl peroxyneodecanoate, t-hexyl peroxyneodecanoate, t-butyl peroxypivalate, 1,1,3,3-tetramethylbutylperoxy-2-ethylhexanoate, 2,5-dimethyl-2,5-di(2-ethylhexanoylperoxy)hexane, 1-cyclohexyl-1-methylethylperoxy-2-ethylhexanoate, t-hexylperoxy-2-ethylhexanoate, t-butylperoxy-2-ethylhexanoate, t-butyl peroxyisobutyrate, 1,1-bis(t-butylperoxy)cyclohexane, t-hexylperoxyisopropyl monocarbonate, t-butylperoxy-3,5,5-trimethylhexanoate, t-butyl peroxylaurate, 2,5-dimethyl-2,5-di(m-toluoylperoxy)hexane, t-butylperoxyisopropyl monocarbonate, t-butylperoxy-2-ethylhexyl monocarbonate, t-hexyl peroxybenzoate, and t-butyl peroxyacetate.

Examples of the peroxy ketals include 1,1-bis(t-hexylperoxy)-3,3,5-trimethylcyclohexane, 1,1-bis(t-hexylperoxy)cyclohexane, 1,1-bis(t-butylperoxy)-3,3,5-trimethylcyclohexane, 1,1-(t-butylperoxy)cyclododecane, and 2,2-bis(t-butylperoxy)decane.

Examples of the dialkyl peroxides include α,α′-bis(t-butylperoxy)diisopropylbenzene, dicumyl peroxide, 2,5-dimethyl-2,5-di(t-butylperoxy)hexane, and t-butylcumyl peroxide.

Examples of the hydroperoxides include diisopropylbenzene hydroperoxide and cumene hydroperoxide.

These radical polymerization initiators may be used by being mixed with a decomposition accelerator, an inhibitor, or the like. Furthermore, those in which these radical polymerization initiators are coated with a polyurethane-based or polyester-based polymer substance or the like and microencapsulated are preferable because storage property is extended.

From the viewpoint of pot life, the content of the component (C) in the adhesive agent composition may be 0.1 mass % or more, 0.5 mass % or more, or 1 mass % or more, may be 20 mass % or less, 10 mass % or less, or 5 mass % or less, and may be 0.1 to 20 mass %, 0.5 to 10 mass %, or 1 to 5 mass %, based on the total mass of the resin components (for example, components other than the conductive particles and the non-conductive filler) of the adhesive agent composition.

### [Conductive Particles]

The conductive particles may be metal particles such as Au, Ag, Ni, Cu, and solder, conductive carbon particles composed of conductive carbon, and the like. Furthermore, the conductive particles may be formed by coating the surface of a transition metal such as Ni with a noble metal such as Au. From the viewpoint of obtaining a sufficient pot life, the surface layer can be a noble metal such as Au, Ag, or a platinum group metal, and may be Au. Furthermore, the conductive particles may be a coated conductive particles in which a conductive layer is formed on the surface of a non-conductive particle by a method such as coating the surface of a non-conductive particle of glass, ceramic, plastic, or the like with the above-described conductive substance, and the outermost layer is composed of a noble metal. In the case of using such particles or hot-melt metal particles, since the particles have deformability by heating and pressurization, the contact area with the electrode at the time of connection increases, and the reliability can be improved.

The conductive particles may be insulating coated conductive particles including the above-described metal particles, conductive carbon particles, or coated conductive particles, and an insulating layer containing an insulating material such as a resin and coating the surfaces of the particles. When the conductive particles are insulating coated conductive particles, even in a case where the content of the conductive particles is large, since the surfaces of the particles are coated with the resin, occurrence of a short circuit due to contact between the conductive particles can be suppressed, and insulation between adjacent electrode circuits can be improved.

As the conductive particles, one kind of the above-described various conductive particles is used singly or two or more kinds thereof are used in combination.

The maximum particle diameter of the conductive particles needs to be smaller than the minimum interval between the electrodes (the shortest distance between the adjacent electrodes). The maximum particle diameter of the conductive particles may be 1.0 μm or more, 2.0 μm or more, or 2.5 μm or more from the viewpoint of excellent dispersibility and conductivity. The maximum particle diameter of the conductive particles may be 50 μm or less, 30 μm or less, or 20 μm or less from the viewpoint of excellent dispersibility and conductivity. From these viewpoints, the maximum particle diameter of the conductive particles may be 1.0 to 50 μm, 2.0 to 30 μm, or 2.5 to 20 μm. In the present specification, the particle diameter of 300 arbitrary conductive particles (pcs) is measured by observation using a scanning electron microscope (SEM), and the largest value obtained is taken as the maximum particle diameter of the conductive particles. In a case where the shape of the conductive particles is not spherical, such as in a case where the conductive particles have protrusions, the particle diameter of the conductive particles is the diameter of a circle circumscribing the conductive particles in the SEM image.

The average particle diameter of the conductive particles may be 1.0 μm or more, 2.0 μm or more, or 2.5 μm or more from the viewpoint of excellent dispersibility and conductivity. The average particle diameter of the conductive particles may be 50 μm or less, 30 μm or less, or 20 μm or less from the viewpoint of excellent dispersibility and conductivity. From these viewpoints, the average particle diameter of the conductive particles may be 1.0 to 50 μm, 2.0 to 30 μm, or 2.5 to 20 μm. In the present specification, the particle diameter of 300 arbitrary conductive particles (pcs) is measured by observation using a scanning electron microscope (SEM), and the average value of the obtained particle diameters is taken as the average particle diameter.

The content of the conductive particles in the adhesive agent composition may be in a range of 0.1 to 30 parts by volume with respect to 100 parts by volume of the resin components (for example, components other than the conductive particles and the non-conductive filler) of the adhesive agent composition from the viewpoint of easily obtaining a stable connection resistance. The content of the conductive particles may be 0.1 to 10 parts by volume from the viewpoint of preventing a short circuit or the like between adjacent circuits due to excessive conductive particles.

Furthermore, from the viewpoint of easily obtaining a stable connection resistance, the content of the conductive particles may be 0.5 to 60 mass %, 3 to 45 mass %, or 6 to 30 mass %, based on the total mass of the resin components (for example, components other than the conductive particles and the non-conductive filler) of the adhesive agent composition.

### [Non-Conductive Filler]

The adhesive agent composition of the present embodiment contains, as a non-conductive filler, a non-conductive filler MF (hereinafter, also referred to as “component (MF)”) having an average linear thermal expansion coefficient of 0 ppb/° C. or less from 30° C. to 150° C.

When the adhesive agent composition of the present embodiment contains the component (MF), a circuit connection structure excellent in high-temperature and high-humidity connection reliability can be obtained. It is presumed by the present inventors that such an effect has been exhibited because both the stress applied to the outside due to expansion of the cured product of the adhesive agent composition constituting the connection portion by heating and the stress applied to the inside due to contraction of the cured product after heating can be alleviated by the component (MF).

The average linear thermal expansion coefficient of the filler from 30° C. to 150° C. can be measured by, for example, a method such as a thermal expansion meter that detects elongation of a sample by a laser interferometer, or an X-ray diffraction method.

The component (MF) may be an inorganic filler or a spherical inorganic filler from the viewpoint of reducing the melt viscosity, further reducing the connection resistance, and improving the high-temperature and high-humidity connection reliability.

Examples of the inorganic filler include a glass filler, a zirconium phosphate-based filler, a cordierite-based filler, a silicon oxide-based filler, a zirconium tungstate-based filler, and a manganese nitride-based filler. Among these, one or more selected from a glass filler and a zirconium phosphate-based filler can be used from the viewpoint of reducing the melt viscosity, further reducing the connection resistance, and improving the high-temperature and high-humidity connection reliability. The glass filler may be a titanium-doped glass filler or a titanium-doped spherical glass filler.

As the component (MF), a commercially available product can be used. Examples of the commercially available product include “DL7400” (manufactured by Nippon Electric Glass Co., Ltd., trade name, linear thermal expansion coefficient (average value at 30 to 150° C.): −1.1 ppm/° C.), “AZ filler” (manufactured by Asahi Glass Co., Ltd., trade name, linear thermal expansion coefficient (average value at 30 to 150° C.): 0.2 ppm/° C.), and “ZWP” (manufactured by KCM Corporation, trade name, linear thermal expansion coefficient (average value at 30 to 150° C.): −0.3 ppm/° C.).

The average particle diameter (primary particle diameter) of the component (MF) may be 5 nm to 5 μm, 1 μm to 5 μm, 5 nm to 2 μm, 10 nm to 100 nm, or 10 nm to 30 nm from the viewpoint of increasing the contact area between the conductive particles and the electrode, further reducing the connection resistance, and improving the high-temperature and high-humidity connection reliability.

The specific gravity of the component (MF) may be 1 g/cm³ to 7 g/cm³, 1 g/cm³ to 5 g/cm³, or 1.5 g/cm³ to 3 g/cm³ from the viewpoint of prevention of varnish separation and composition uniformity in the film.

The content of the component (MF) may be 0.1 to 50 mass % or 5 to 25 mass % based on the total mass of the adhesive agent composition (resin components) excluding the conductive particles and the non-conductive filler.

The content of the component (MF) may be 1 mass % or more, 50 mass % or more, 75 mass % or more, 90 mass % or more, or 100 mass %, based on the total amount of the non-conductive filler contained in the adhesive agent composition.

The adhesive agent composition of the present embodiment may contain a non-conductive filler other than the component (MF). The other non-conductive filler may be either an inorganic filler or an organic filler. Examples of the inorganic filler include metal oxide fine particles such as silica fine particles, alumina fine particles, silica-alumina fine particles, titania fine particles, and zirconia fine particles; and inorganic fine particles such as nitride fine particles. Examples of the organic filler include organic fine particles such as silicone fine particles, methacrylate-butadiene-styrene fine particles, acryl-silicone fine particles, polyamide fine particles, and polyimide fine particles.

The adhesive agent composition of the present embodiment may further contain other components which are other than the above-described components. Examples of the other components include a thiol compound (hereinafter, also referred to as the component (D)), and a coupling agent (hereinafter, also referred to as the component (E)). These components can be used singly or in combination of two or more kinds thereof.

The thiol compound as the component (D) may be a thiol compound having one thiol group (monofunctional thiol compound) or a thiol compound having a plurality of thiol groups (polyfunctional thiol compound).

The thiol group of the component (D) may be a primary thiol group, a secondary thiol group, or a tertiary thiol group.

Examples of the monofunctional thiol compound include 2-mercaptobenzothiazole, 2-methyl-4,5-dihydrofuran-3-thiol, 3-mercapto-1-hexanol, mercaptomethylbutanol, 3-mercapto-2-methylpentanol, 3-mercapto-3-methylbutanol, 4-ethoxy-2-methyl-2-butanethiol, hexanethiol, isobutylthiol, 1,1-dimethylheptanethiol, 2-ethylhexyl-3-mercaptopropionate, n-octyl-3-mercaptopropionate, methoxybutyl-3-mercaptopropionate, and stearyl-3-mercaptopropionate.

Examples of the polyfunctional thiol compound include pentaerythritol tetrakis(3-mercaptobutyrate), ethanedithiol, 1,3-propanethiol, 1,4-butanethiol, trimethylolpropane tris(3-mercaptopropionate), tris-[(3-mercaptopropionyloxy)-ethyl]-isocyanurate, and tetraethylene glycol bis(3-mercaptopropionate).

From the viewpoint of suppressing peeling at the interface between the adhesive agent composition after curing and the circuit member and suppressing an increase in connection resistance of the circuit connection structure, the content of the component (D) may be 0.05 mass % or more, 0.5 mass % or more, 1.0 mass % or more, or 1.5 mass % or more, based on the total mass of the resin components (for example, components other than the conductive particles and the non-conductive filler) of the adhesive agent composition. Furthermore, from the viewpoint of suppressing peeling at the interface between the adhesive agent composition after curing and the circuit member and suppressing an increase in connection resistance of the circuit connection structure, the content of the component (D) may be 5.0 mass % or less, 3.0 mass % or less, 2.5 mass % or less, or 2.0 mass % or less, based on the total mass of the resin components (for example, components other than the conductive particles and the non-conductive filler) of the adhesive agent composition.

As the coupling agent as the component (E), from the viewpoint of improving the adhesion, a compound having at least one of a vinyl group, an acrylic group (acryloyl group), an amino group, an epoxy group, and an isocyanate group can be used. The coupling agent may be a silane coupling agent, and examples thereof include vinyltrimethoxysilane, vinyltriethoxysilane, 3-glycidoxypropyltrimethoxysilane, 3-glycidoxypropylmethyldiethoxysilane, 3-(meth)acryloxypropylmethyldimethoxysilane, 3-(meth)acryloxypropyltrimethoxysilane, 3-(meth)acryloxypropylmethyldiethoxysilane, 3-(meth)acryloxypropyltriethoxysilane, N-2-(aminoethyl)-3-aminopropylmethyldimethoxysilane, N-phenyl-3-aminopropyltrimethoxysilane, 3-ureidopropyltriethoxysilane, 3-mercaptopropyltrimethoxysilane, 3-isocyanatopropyltriethoxysilane, and condensates thereof. These may be used singly, or in combination of two or more kinds thereof.

The content of the component (E) may be 0.5 mass % or more, 1 mass % or more, or 2 mass % or more, and may be 15 mass % or less, 10 mass % or less, or 5 mass % or less, based on the total mass of the resin components (for example, components other than the conductive particles and the non-conductive filler) of the adhesive agent composition.

Furthermore, the adhesive agent composition of the present embodiment may contain other additives such as a softener, an accelerator, an anti-aging agent, a colorant, a flame retardant, a thixotropic agent, and a polymerization inhibitor. Examples of the polymerization inhibitor include hydroquinone and methyl ether hydroquinone.

The reaction rate of the adhesive agent composition of the present embodiment when heated at 180° C. for 1 minute may be 80% or more or 90% or more. The reaction rate is determined by the following procedure.

### (Reaction Rate)

Two adhesive agent compositions (5 mg) are prepared as samples before heating. Next, one sample before heating is heated at 180° C. for 1 minute in an air atmosphere (atmosphere) to obtain a sample after heating. For each of the sample before heating and the sample after heating, the calorific value of DSC is measured at a temperature rising rate of 10° C./min in a measurement temperature range of 30° C. to 250° C. under a nitrogen flow using a differential scanning calorimetry (DSC) device (product name: DSC7, manufactured by PerkinElmer Japan). Based on the measured calorific value of DSC, the reaction rate at the time of heating at 180° C. for 1 minute is determined from the following formula.

$$Reaction rate = ( Cx - Cy ) \times 100 / Cx$$

In the formula, Cx represents a DSC calorific value (J/g) of the sample before heating, and Cy represents a DSC calorific value (J/g) of the sample after heating.

### <Adhesive Agent Film for Circuit Connection>

An adhesive agent film for circuit connection of the present embodiment can contain a thermoplastic resin, a thermosetting component, conductive particles, and a non-conductive filler, and can have the same configuration as that of the adhesive agent composition of the present embodiment described above.

Note that, as for the content of each component, “based on the total amount of the adhesive agent composition” is replaced with “based on the total amount of the adhesive agent film”, and “based on the total mass of the resin components (for example, components other than the conductive particles and the non-conductive filler) of the adhesive agent composition” is replaced with “based on the total mass of the resin components (for example, components other than the conductive particles and the non-conductive filler) of the adhesive agent film”.

The reaction rate of the adhesive agent film for circuit connection of the present embodiment when heated at 180° C. for 1 minute may be 80% or more or 90% or more. The reaction rate is determined in the same manner as described above except that two adhesive agent films (5 mg) are prepared as samples before heating.

The particle density of the conductive particles in the adhesive agent film for circuit connection may be 100 particles/mm² or more, 1000 particles/mm² or more, or 3000 particles/mm² or more from the viewpoint of obtaining a stable connection resistance. The particle density of the conductive particles in the adhesive agent film for circuit connection may be 100000 particles/mm² or less, 50000 particles/mm² or less, or 30000 particles/mm² or less from the viewpoint of securing insulation between the adjacent electrodes. From these viewpoints, the particle density of the conductive particles in the adhesive agent film for circuit connection may be 100 to 100000 particles/mm², 1000 to 50000 particles/mm², or 3000 to 30000 particles/mm².

The thickness of the adhesive agent film for circuit connection may be, for example, 3 μm or more or 10 μm or more, and may be 50 μm or less, 30 μm or less, or 20 μm or less.

The adhesive agent film for circuit connection of the present embodiment can be suitably used as an adhesive agent film for circuit connection for connecting a first circuit member having a first electrode (for example, a first circuit member in which a first circuit electrode is formed on a main surface of a first substrate) and a second circuit member having a second electrode (for example, a second circuit member in which a second circuit electrode is formed on a main surface of a second substrate) in a state where the first electrode and the second electrode (first circuit electrode and the second circuit electrode) are arranged to face each other.

The adhesive agent film for circuit connection may have a multilayer structure of two or more layers from the viewpoint of easily obtaining a stable connection resistance.

The adhesive agent film for circuit connection of the present embodiment can be produced by the following method. Specifically, first, the component (A), the thermosetting component (for example, the component (B) and the component (C)), the conductive particles, the non-conductive filler MF, and other components added as necessary are added to a solvent (organic solvent), and dissolved or dispersed by stirring, mixing, kneading, or the like to prepare a varnish composition (varnish-like adhesive agent composition). Thereafter, the varnish composition is applied onto the release-treated substrate using a knife coater, a roll coater, an applicator, a comma coater, a die coater, or the like, and then the solvent is volatilized by heating to form an adhesive agent film for circuit connection on the base material.

As the solvent used for preparing the varnish composition, a solvent having a property of uniformly dissolving or dispersing each component may be used. Examples of such a solvent include toluene, acetone, methyl ethyl ketone, methyl isobutyl ketone, ethyl acetate, propyl acetate, and butyl acetate. These solvents can be used singly or in combination of two or more kinds thereof. The stirring and mixing and the kneading in the preparation of the varnish composition can be performed using, for example, a stirrer, a mixer, a triple roll, a ball mill, a bead mill, or a homodisper.

The base material is not particularly limited as long as it has heat resistance capable of withstanding heating conditions at the time of volatilizing the solvent, and for example, a base material (for example, a film) made of stretched polypropylene (OPP), polyethylene terephthalate (PET), polyethylene naphthalate, polyethylene isophthalate, polybutylene terephthalate, polyolefin, polyacetate, polycarbonate, polyphenylene sulfide, polyamide, polyimide, cellulose, an ethylene-vinyl acetate copolymer, polyvinyl chloride, polyvinylidene chloride, synthetic rubber-based material, a liquid crystal polymer, or the like can be used.

The heating condition at the time of volatilizing the solvent from the varnish composition applied to the base material may be a condition under which the solvent is sufficiently volatilized. The heating condition may be, for example, 40° C. or higher and 120° C. or lower for 0.1 minutes or more and 10 minutes or less.

In the adhesive agent film for circuit connection of the present embodiment, a part of the solvent may remain without being removed. The content of the solvent in the adhesive agent film for circuit connection of the present embodiment may be 10 mass % or less or 5 mass % or less, for example, based on the total mass of the adhesive agent film.

### <Circuit Connection Structure and Method for Manufacturing Same>

Next, a circuit connection structure and a method for manufacturing the same will be described.

A circuit connection structure of the present embodiment includes: a first circuit member having a first electrode; a second circuit member having a second electrode; and a connection portion disposed between the first circuit member and the second circuit member and electrically connecting the first electrode and the second electrode to each other, in which the connection portion contains conductive particles and a non-conductive filler MF having an average linear thermal expansion coefficient of 0 ppb/° C. or less from 30° C. to 150° C. The connection portion may contain a cured product of the adhesive agent composition of the present embodiment or the adhesive agent film for circuit connection of the present embodiment.

A method for manufacturing a circuit connection structure of the present embodiment includes a step of heating and pressurizing a first circuit member having a first electrode, a second circuit member having a second electrode, and the adhesive agent film for circuit connection of the present embodiment in a state where the first electrode and the second electrode are disposed to face each other with the adhesive agent film for circuit connection interposed therebetween so as to electrically connect the first electrode and the second electrode.

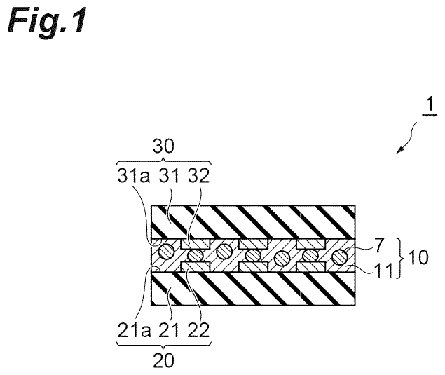

FIG. 1 is a schematic cross-sectional view illustrating one embodiment of a circuit connection structure. A circuit connection structure 1 illustrated in FIG. 1 includes a first circuit member 20 having a first circuit board 21 and a first circuit electrode (first connecting terminal) 22 formed on a main surface 21a of the first circuit board 21, a second circuit member 30 having a second circuit board 31 and a second circuit electrode (second connecting terminal) 32 formed on a main surface 31a of the second circuit board 31, and a connection portion 10 interposed between the first circuit member 20 and the second circuit member 30 and connecting these circuit members. The second circuit member 30 is arranged to face the first circuit member 20 such that the second circuit electrode 32 faces the first circuit electrode 22.

The connection portion 10 is formed by interposing the adhesive agent film for circuit connection of the present embodiment between the first circuit member 20 and the second circuit member 30 and pressurizing the adhesive agent film for circuit connection in that state, and includes a cured product of the adhesive agent film for circuit connection. Note that, in the present embodiment, an example is illustrated in which the connection portion 10 is formed using an adhesive agent film for circuit connection containing conductive particles, and the connection portion 10 is composed of an insulating layer 11 and conductive particles 7 dispersed in the insulating layer 11. The insulating layer 11 is derived from a component other than the conductive particles in the adhesive agent film, and can contain, for example, a cured body formed by radical polymerization of a radical polymerizable compound.

The first circuit electrode 22 and the second circuit electrode 32 facing each other are electrically connected via the conductive particles 7. On the other hand, the first circuit electrodes 22 and the second circuit electrodes 32 formed on the same circuit board are insulated from each other, respectively.

Examples of the first circuit board 21 and the second circuit board 31 include chip parts such as a semiconductor chip, a resistor chip, and a capacitor chip, and substrates such as a printed board. Usually, the circuit member is provided with a large number of connecting terminals, but the number of connecting terminals may be one depending on the case

More specifically, a substrate of a semiconductor or an inorganic material such as glass or ceramic, a plastic substrate, or a glass/epoxy substrate is used. Examples of the plastic substrate include a polyimide film, a polycarbonate film, and a polyester film. The first circuit electrode and the second circuit electrode are formed of a metal such as copper. In order to obtain more favorable electrical connection, the surface of at least one of the first circuit electrode and the second circuit electrode is preferably made of a metal selected from gold, silver, tin, and a platinum group metal. The surface layer is selected from any one of gold, silver, a platinum group metal, and tin, and these may be used in combination. Furthermore, a multilayer configuration may be formed by combining a plurality of metals such as copper/nickel/gold.

Furthermore, one of the first circuit member 20 and the second circuit member 30 may be a liquid crystal display panel having a glass substrate or a plastic substrate as a circuit board and having a connecting terminal formed of ITO or the like. Furthermore, one of the first circuit member 20 and the second circuit member 30 may be a flexible printed wiring circuit (FPC) having a polyimide film as a circuit board, a tape carrier package (TCP) or a chip-on-film(COF), or a semiconductor silicon chip having a semiconductor substrate as a circuit board. These various circuit members are appropriately combined as necessary to form a circuit connection structure.

Note that the substrate provided with the circuit electrode is preferably subjected to a heating treatment in advance before a connecting step with the adhesive agent film for circuit connection in order to eliminate the influence of volatile components due to heating at the time of connection.

The circuit connection structure 1 is formed, for example, by superimposing the first circuit member 20, the adhesive agent film for circuit connection, and the second circuit member 30 in this order such that the first connecting terminal 22 and the second connecting terminal 32 face each other, and pressurizing or further heating them in this state. The pressure is not particularly limited as long as it does not damage an adherend, and is generally preferably 0.1 to 10 MPa. The heating temperature is not particularly limited, and is preferably 100 to 200° C. These pressurization and heating are preferably performed in a range of 0.5 seconds to 100 seconds, and bonding can be performed even by heating at 130 to 180° C. and 3 MPa for 10 seconds.

### EXAMPLES

Hereinafter, the present invention will be described more specifically with reference to examples, but the present invention is not limited to examples.

### <Synthesis of Polyurethane Resin (PU1)>

To a separable flask equipped with a reflux condenser, a thermometer, and a stirrer, 1000 parts by mass of polypropylene glycol (number average molecular weight: 2000), which is a diol having an ether bond, and 4000 parts by mass of methyl ethyl ketone as a solvent were added and stirred at 40° C. for 30 minutes. This solution was heated to 70° C., and then 0.127 parts by mass of dimethyl tin laurate as a catalyst was added thereto. Subsequently, a solution prepared by dissolving 125 parts by mass of 4,4′-diphenylmethane diisocyanate in 125 parts by mass of methyl ethyl ketone was added dropwise to this solution over 1 hour. Thereafter, stirring was continued at 70° C. until an absorption peak derived from an NCO group was not observed with an infrared spectrophotometer, thereby obtaining a methyl ethyl ketone solution of a polyurethane resin (PU1). Then, the amount of methyl ethyl ketone was adjusted so that the solid content concentration (concentration of the polyurethane resin) of this solution was 30 mass %. The weight average molecular weight of the polyurethane resin (PU1) was 50000. Note that the weight average molecular weight was measured by gel permeation chromatography (GPC) using a calibration curve by standard polystyrene under the following conditions.

### (Measurement Conditions)

Device: GPC-8020 manufactured by TOSOH CORPORATION
Detector: RI-8020 manufactured by TOSOH CORPORATION
Column: Gelpack GLA160S+GLA150SG2000Hhr manufactured by Resonac Corporation
Sample concentration: 120 mg/3 mL
Solvent: Tetrahydrofuran
Injection amount: 60 μL
Pressure: 2.94×10⁶ Pa (30 kgf/cm²)
Flow rate: 1.00 mL/min

### <Synthesis of Polyurethane Acrylate (UA1)>

To a reaction vessel equipped with a stirrer, a thermometer, a reflux condenser having a calcium chloride drying tube, and a nitrogen gas introduction tube, 2500 parts by mass (2.50 mol) of poly(1,6-hexanediol carbonate) (trade name: DURANOL T5652, manufactured by Asahi Kasei Chemicals Corporation, number average molecular weight: 1000) and 666 parts by mass (3.00 mol) of isophorone diisocyanate (manufactured by Sigma-Aldrich Co. LLC) were uniformly added dropwise for 3 hours. Next, a sufficient amount of nitrogen gas was introduced into the reaction vessel, and then, the inside of the reaction vessel was heated to 70 to 75° C. for reaction. Next, 0.53 parts by mass (4.3 mmol) of hydroquinone monomethyl ether (manufactured by Sigma-Aldrich Co. LLC) and 5.53 parts by mass (8.8 mmol) of dibutyltin dilaurate (manufactured by Sigma-Aldrich Co. LLC) were added to the reaction vessel, 238 parts by mass (2.05 mol) of 2-hydroxyethyl acrylate (manufactured by Sigma-Aldrich Co. LLC) was added, and then, a reaction was performed at 70° C. for 6 hours in an air atmosphere. As a result, polyurethane acrylate (UA1) was obtained. The weight average molecular weight of the polyurethane acrylate (UA1) was 15000. Note that the weight average molecular weight was measured in the same manner as in the weight average molecular weight of the polyurethane resin described above.

### <Production of Conductive Particles>

A layer made of nickel was formed on the surface of polystyrene particles so that the thickness of the layer was 0.2 μm, thereby obtaining conductive particles having an average particle diameter of 4 μm, a maximum particle diameter of 4.5 μm, and a specific gravity of 2.5.

### Examples 1 to 3 and Comparative Examples 1 to 4

### [Production of Adhesive Agent Film]

The components shown below were mixed in blending amounts (parts by mass) shown in Table 1 to prepare varnish compositions.

### (Thermoplastic Resin)

A1: Polyurethane resin (PU1) synthesized as described above
A2: Using 40 mass % of a solution prepared by dissolving 40 g of a bisphenol A type phenoxy resin (trade name: PKHC, manufactured by Union Carbide Corporation) in 60 g of methyl ethyl ketone (the blending amount in the table indicates the blending amount of the bisphenol A type phenoxy resin)

### (Radical Polymerizable Compound)

B1: Polyurethane acrylate (UA1) synthesized as described above
B2: Isocyanuric acid EO-modified diacrylate (product name: M-215, manufactured by TOAGOSEI CO., LTD.)
B3: Diacrylate having a tricyclodecane skeleton (dicyclopentadiene type diacrylate) (trade name: DCP-A, manufactured by Kyoeisha Chemical Co., Ltd.)
B4: 2-Methacryloyloxyethyl acid phosphate (trade name: Light Ester P-2M, manufactured by Kyoeisha Chemical Co., Ltd.)

### (Radical Polymerization Initiator)

C1: Benzoyl peroxide (trade name: NYPER BMT-K40, manufactured by NOF Corporation)
C2: Lauroyl peroxide (product name: PEROYL L, manufactured by NOF Corporation)

### (Coupling Agent)

E1: 3-Methacryloxypropyltrimethoxysilane (trade name: KBM503, manufactured by Shin-Etsu Chemical Co., Ltd.)

### (Non-Conductive Filler)

F1: Spherical glass filler(“DL7400” (manufactured by Nippon Electric Glass Co., Ltd., trade name, linear thermal expansion coefficient (average value at 30 to 150° C.): −1.1 ppm/° C., average particle diameter (primary particle diameter): 2 μm)
F2: Silica fine particles (trade name: R104, manufactured by Nippon Aerosil Co., Ltd., average particle diameter (primary particle diameter): 12 nm)

### (Conductive Particles)

G1: Conductive particles produced as described above

The varnish composition obtained above was applied onto a PET film having a thickness of 50 μm using a coating apparatus. Subsequently, hot air drying was performed at 70° C. for 3 minutes to form an adhesive agent film having a thickness (thickness after drying) of 10 μm on the PET film.

[Reaction Rate when Adhesive Agent Film Was Heated at 180° C. for 1 Minute]

The reaction rate when the adhesive agent film was heated at 180° C. for 1 minute was determined by the following procedure.

### (Reaction Rate)

Two adhesive agent compositions (5 mg) were prepared as samples before heating. Next, one sample before heating was heated at 180° C. for 1 minute in an air atmosphere (atmosphere) to obtain a sample after heating. For each of the sample before heating and the sample after heating, the calorific value of DSC was measured at a temperature rising rate of 10° C./min in a measurement temperature range of 30° C. to 250° C. under a nitrogen flow using a differential scanning calorimetry (DSC) device (product name DSC7, manufactured by PerkinElmer Japan). Based on the measured calorific value of DSC, the reaction rate at the time of heating at 180° C. for 1 minute was determined from the following formula.

$$Reaction rate = ( Cx - Cy ) \times 100 / Cx$$

In the formula, Cx represents a DSC calorific value (J/g) of the sample before heating, and Cy represents a DSC calorific value (J/g) of the sample after heating.

The reaction rate of the adhesive agent films of Examples 1 to 3 and Comparative Examples 1 to 4 was 90% or more.

### [Production of Circuit Connection Structure]

A COF (manufactured by FLEXCEED Co., Ltd.) having a pitch of 25 μm and a glass substrate with a thin film electrode (manufactured by GEOMATEC Co., Ltd.) including a thin film electrode (height: 1200 Å) made of silicon nitride (SiNx) on a glass substrate were connected via the prepared adhesive agent film over a width of 1 mm by performing heating and pressurization at 180° C. and 4.5 MPa for 4 seconds using a thermocompression bonding device (heating method: constant heat type, manufactured by TAIYO KIKAI Ltd.) thereby preparing a circuit connection structure (connection structure).

### [Evaluation of Circuit Connection Structure]

The obtained circuit connection structure was evaluated as follows.

### (Connection Resistance)

For the obtained circuit connection structure, connection resistance values between opposing electrodes immediately after connection and after a high-temperature and high-humidity test were measured with a multimeter. The high-temperature and high-humidity test was performed by leaving the circuit connection structure to stand for 100 h in a thermo-hygrostat at 85° C. and 85% RH. The connection resistance value was determined as an average of 16 points of resistance between opposing electrodes.

### (Peeling)

For the connection structure produced as described above, the connection appearance immediately after connection and after the high-temperature and high-humidity test in which the connection structure was left to stand in a thermo-hygrostat at 110° C. and 85% RH for 100 hours was observed using an optical microscope, and the peeling occurrence area of the substrate-resin interface in a space part (a part between the electrode terminal and the electrode terminal of the FPC) was measured and evaluated according to the following criteria.

### [Criteria]

A: The ratio of the peeling occurrence area to the total area of the space part is 10% or less.
B: The ratio of the peeling occurrence area to the total area of the space part is more than 10% and 20% or less.
C: The ratio of the peeling occurrence area to the total area of the space part is more than 20% and 30% or less.
D: The ratio of the peeling occurrence area to the total area of the space part is more than 30% and 40% or less.
E: The ratio of the peeling occurrence area to the total area of the space part is more than 40%.

TABLE 1

| | | | Example | Example | Example | Comparative | Comparative | Comparative | Comparative |
|---|---|---|---|---|---|---|---|---|---|
| | | | 1 | 2 | 3 | Example 1 | Example 2 | Example 3 | Example 4 |
| Composition | Thermoplastic resin | A1 | 37 | 37 | 37 | 37 | 37 | 37 | 15 |
| (parts by mass) | | A2 | — | — | — | — | — | — | 15 |
| | Radical | B1 | 30 | 30 | 30 | 30 | 30 | 30 | 60 |
| | polymerizable | B2 | — | — | — | — | — | — | 10 |
| | compound | B3 | 19 | 19 | 19 | 19 | 19 | 19 | — |
| | | B4 | 1.4 | 1.4 | 1.4 | 1.4 | 1.4 | 1.4 | 3 |
| | Polymerization | C1 | 2 | 2 | 2 | 2 | 2 | 2 | — |
| | initiator | C2 | — | — | — | — | — | — | 3 |
| | Coupling agent | E1 | 1 | 1 | 1 | 1 | 1 | 1 | 3 |
| | Non-conductive | F1 | 4.5 | 15 | 36 | — | — | — | — |
| | filler | F2 | — | — | — | 4.5 | 15 | 36 | 15 |
| | Conductive particles | G1 | 6 | 6 | 6 | 6 | 6 | 6 | 6 |

| | | | | | | | |
|---|---|---|---|---|---|---|---|
| Initial connection resistance value (Ω) | 2.5 | 2.6 | 4.3 | 2.6 | 2.9 | 65.3 | 2.6 |
| Connection resistance value (Ω) after | 6.3 | 6.7 | 10.5 | 11.9 | 13.3 | 172.9 | 11.5 |
| high-temperature and high-humidity test | | | | | | | |
| Initial peeling area | A | A | A | A | A | A | A |
| Peeling area after high-temperature | A | A | A | C | C | D | D |
| and high-humidity test | | | | | | | |

As shown in Table 1, according to the adhesive agent films of Examples 1 to 3 containing a non-conductive filler having an average linear thermal expansion coefficient of 0 ppb/° C. or less from 30° C. to 150° C., it is possible to reduce peeling occurring in the connection structure after the high-temperature and high-humidity test and to obtain a circuit connection structure excellent in high-temperature and high-humidity connection reliability.

### REFERENCE SIGNS LIST

1 Circuit connection structure
7 Conductive particles
10 Connection portion
11 Insulating layer
20 First circuit member
21 First circuit board
22 First circuit electrode (first connecting terminal)
30 Second circuit member
31 Second circuit board
32 Second circuit electrode (second connecting terminal)

1. An adhesive agent composition comprising: a thermosetting component; conductive particles; and a non-conductive filler, wherein
the non-conductive filler includes a non-conductive filler MF having an average linear thermal expansion coefficient of 0 ppb/° C. or less from 30° C. to 150° C.

2. The adhesive agent composition according to claim 1, wherein a content of the non-conductive filler MF is 0.1 to 50 mass % based on a total mass of the adhesive agent composition excluding the conductive particles and the non-conductive filler.

3. The adhesive agent composition according to claim 1, comprising a radical polymerizable compound and a radical polymerization initiator as the thermosetting component.

4. The adhesive agent composition according to claim 1, further comprising a thermoplastic resin.

5. The adhesive agent composition according to claim 1, wherein a reaction rate when the adhesive agent composition is heated at 180° C. for 1 minute is 90% or more.

6. An adhesive agent film for circuit connection, comprising: a thermoplastic resin; a thermosetting component; conductive particles; and a non-conductive filler, wherein
the non-conductive filler includes a non-conductive filler MF having an average linear thermal expansion coefficient of 0 ppb/° C. or less from 30° C. to 150° C.

7. The adhesive agent film for circuit connection according to claim 6, wherein a content of the non-conductive filler MF is 0.1 to 50 mass % based on a total mass of the adhesive agent film excluding the conductive particles and the non-conductive filler.

8. The adhesive agent film for circuit connection according to claim 6, comprising a radical polymerizable compound and a radical polymerization initiator as the thermosetting component.

9. The adhesive agent film for circuit connection according to claim 6, wherein a reaction rate when the adhesive agent film for circuit connection is heated at 180° C. for 1 minute is 90% or more.

10. A circuit connection structure comprising:
a first circuit member having a first electrode;
a second circuit member having a second electrode; and
a connection portion disposed between the first circuit member and the second circuit member and electrically connecting the first electrode and the second electrode to each other, wherein
the connection portion contains conductive particles and a non-conductive filler MF having an average linear thermal expansion coefficient of 0 ppb/° C. or less from 30° C. to 150° C.

11. The circuit connection structure according to claim 10, wherein the connection portion contains a cured product of the adhesive agent composition according to claim 1.

12. A method for manufacturing a circuit connection structure, the method comprising a step of heating and pressurizing
a first circuit member having a first electrode,
a second circuit member having a second electrode, and
the adhesive agent film for circuit connection according to claim 6
in a state where the first electrode and the second electrode are disposed to face each other with the adhesive agent film for circuit connection interposed therebetween so as to electrically connect the first electrode and the second electrode.
